(19) United States
(12) Patent Application Publication
(10) Pub. No.: US 2026/0245601 A1
(43) Pub. Date: Aug. 20, 2026

(54) SEMICONDUCTOR DEVICE AND METHOD OF MANUFACTURING

(71) Applicant: Kioxia Corporation, Tokyo (JP)

(72) Inventor: Tadashi IGUCHI, Yokkaichi Mie (JP)

(21) Appl. No.: 19/326,373

(22) Filed: Sep. 11, 2025

(30) Foreign Application Priority Data
Feb. 20, 2025 (JP) 2025-026178

(51) Int. Cl. G11C 5/06; G11C 16/04; H10B 43/10; H10B 43/27; H10B 43/35; H10D 30/01; H10D 30/69

(52) U.S. Cl. CPC G11C 5/063; G11C 16/0483; H10B 43/10; H10B 43/27; H10B 43/35; H10D 30/0413; H10D 30/693

(57) ABSTRACT

According to one embodiment, a semiconductor device includes a stacked body on an insulator layer. The stacked body has alternating insulating films and conductive films stacked one upon the other in a first direction. A plurality of pillars extend in the first direction and pass through the stacked body. Each pillar being electrically connected to only a respective one of the conductive films in the stacked body. The stacked body has protruding portions extending into the insulator layer. Each pillar passes through a joining portion of a respective one of the conductive films inside a trench in the insulator layer corresponding in position with a protruding portion. The pillar is electrically connected to the respective one of the conductive films via the joining portion.

### CROSS-REFERENCE TO RELATED APPLICATIONS

This application is based upon and claims the benefit of priority from Japanese Patent Application No. 2025-026178, filed Feb. 20, 2025, the entire contents of which are incorporated herein by reference.

### FIELD

Embodiments described herein relate generally to a semiconductor device and a method of manufacturing the same.

### BACKGROUND

A semiconductor memory device, such as a NAND type flash memory, may have a three-dimensional memory cell array in which a plurality of memory cells are three-dimensionally disposed. In a lead-out region of the three-dimensional memory cell array, a contact for a word line is formed. It is desired to reduce the number of processes for forming such contacts.

### BRIEF DESCRIPTION OF THE DRAWINGS

FIG. 1 is a block diagram of a semiconductor memory device according to a first embodiment.

FIG. 2 is a circuit diagram of a memory cell array of a semiconductor memory device according to a first embodiment.

FIG. 3 is a plan view of a memory cell array of a semiconductor memory device according to a first embodiment.

FIG. 4 is a plan view of a memory region of a semiconductor memory device according to a first embodiment.

FIG. 5 is a cross-sectional view a part of a memory region of a semiconductor memory device according to a first embodiment.

FIG. 6 is a cross-sectional view of a memory pillar of a semiconductor memory device according to a first embodiment.

FIG. 7 is a plan view illustrating a positional relationship of support pillars, trenches, and contact plugs of a semiconductor memory device according to a first embodiment.

FIG. 8A through FIG. 8E depict aspects of a method of manufacturing the semiconductor memory device according to a first embodiment.

FIG. 9 is a cross-sectional of a lead-out region of a semiconductor memory device according to a comparative example.

FIG. 10A through FIG. 10D depict aspects of a method of manufacturing a semiconductor memory device according to a second embodiment.

### DETAILED DESCRIPTION

A semiconductor device capable of being manufactured with a reduced number of processes and a corresponding method of manufacturing a semiconductor device are described.

In general, according to one embodiment, a semiconductor device includes a first stacked body on an insulator layer. The first stacked body includes alternating first insulating films and first conductive films stacked one upon the other in a first direction. A plurality of first pillars extend in the first direction and pass through the first stacked body. Each first pillar is electrically connected to only a respective one of the first conductive films in the first stacked body. The first stacked body has protruding portions extending into the insulator layer. Each first pillar passes through a joining portion of the respective one of the first conductive films inside a trench in the insulator layer corresponding in position with a protruding portion. The first pillar is electrically connected to the respective one of the first conductive films via the joining portion.

Hereinafter, certain example embodiments according to the present disclosure will be described with reference to the attached drawings. These example embodiments do not limit the disclosure. In general, the drawings are schematic or conceptual, and proportions of parts or the like are not necessarily the same as actual ones. In the description and the drawings, components substantially similar to those previously described with reference to a preceding drawing are denoted by same reference symbols and detailed description is appropriately omitted.

### First Embodiment

### Configuration of Semiconductor Memory Device 100

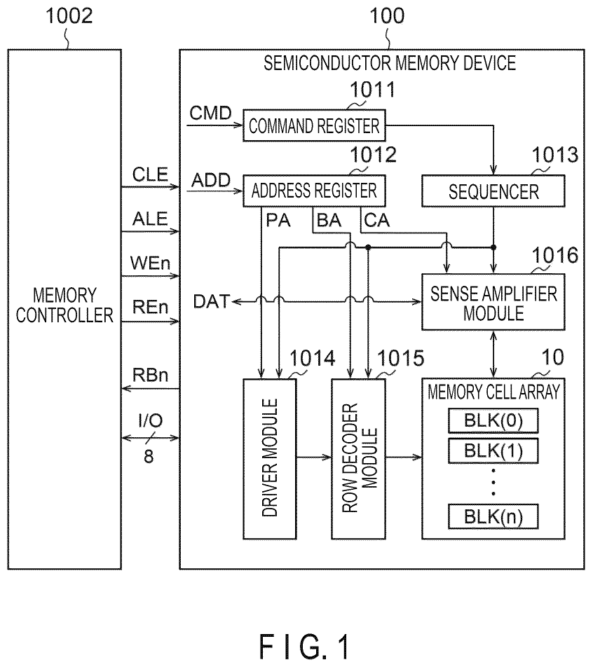

FIG. 1 is a block diagram illustrating a configuration example of a semiconductor memory device 100 according to the first embodiment. The semiconductor memory device 100 is, for example, a NAND type flash memory capable of storing data in a nonvolatile manner and is controlled by an external memory controller 1002. Communication between the semiconductor memory device 100 and the memory controller 1002 supports, for example, a NAND interface standard.

As illustrated in FIG. 1, the semiconductor memory device 100 includes a memory cell array 10, a command register 1011, an address register 1012, a sequencer 1013, a driver module 1014, a row decoder module 1015, and a sense amplifier module 1016.

The memory cell array 10 includes a plurality of blocks BLK(0) to BLK(n) (n is an integer of 1 or more). Each block BLK is a set (group) of memory cells capable of storing data in a nonvolatile manner. The block BLK can be used as, for example, a data erase unit. The memory cell array 10 is provided with a plurality of bit lines and a plurality of word lines. Each memory cell is associated with one bit line and one word line.

The command register 1011 holds a command CMD received by the semiconductor memory device 100 from the memory controller 1002. The command CMD can be, for example, an instruction for causing the sequencer 1013 to execute a read operation, a write operation, an erase operation, or the like.

The address register 1012 holds address information ADD received by the semiconductor memory device 100 from the memory controller 1002. The address information ADD includes, for example, a block address BA, a page address PA, and a column address CA. For example, the block address BA, the page address PA, and the column address CA are used to select the block BLK, the word line, and the bit line, respectively.

The sequencer 1013 controls an operation of the whole semiconductor memory device 100. For example, the sequencer 1013 controls the driver module 1014, the row decoder module 1015, the sense amplifier module 1016, and the like to execute a read operation, a write operation, an erase operation, or the like based on the command CMD held in the command register 1011.

The driver module 1014 generates a voltage used in the read operation, the write operation, the erasure operation, or the like. Then, for example, the driver module 1014 applies the generated voltage to a signal line corresponding to the selected word line based on the page address PA held in the address register 1012.

The row decoder module 1015 includes a plurality of row decoders. The row decoder selects one block BLK in the corresponding memory cell array 10 based on the block address BA held in the address register 1012. Then, the row decoder transfers the voltage applied to the signal line corresponding to the selected word line to the selected word line in the selected block BLK.

In the write operation, the sense amplifier module 1016 applies a desired voltage to each bit line according to write data DAT received from the memory controller 1002. In the read operation, the sense amplifier module 1016 determines (reads) data stored in the memory cell based on the voltage of the bit line, and transfers a determination (read) result to the memory controller 1002 as read data DAT.

The semiconductor memory device 100 and the memory controller 1002 described above may be combined together to form one semiconductor device. Examples of such a semiconductor device include a memory card such as an SD card and an SSD (Solid State Drive).

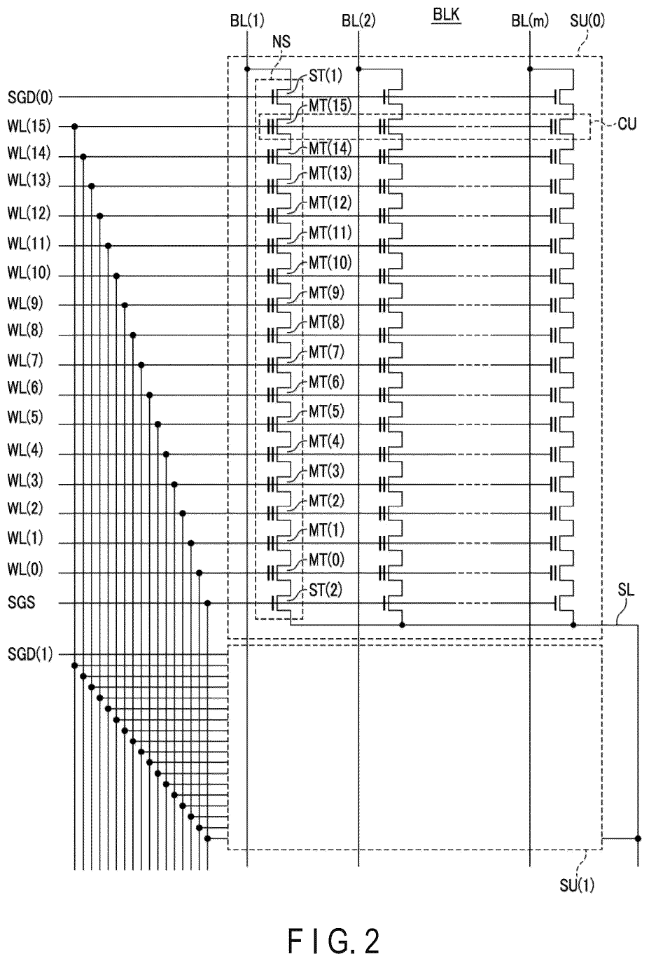

FIG. 2 is a circuit diagram illustrating an example of a circuit configuration of the memory cell array 10. One representative block BLK is extracted from the plurality of blocks BLK included in the memory cell array 10. As illustrated in FIG. 2, the block BLK includes a plurality of string units SU(0) to SU(k) (k is an integer of 1 or more).

Each string unit SU includes a plurality of NAND strings NS each of which is respectively associated with one of the bit lines BL(0) to BL(m) (m is an integer of 1 or more). Each NAND string NS includes, for example, memory cell transistors MT(0) to MT(15) and select transistors ST(1) and ST(2). Each memory cell transistor MT includes a control gate and a charge storage layer and holds data in a nonvolatile manner. The select transistors ST(1) and ST(2) are used to select a string unit SU in the various operations.

In each NAND string NS, the memory cell transistors MT(0) to MT(15) are connected in series. A drain of the select transistor ST(1) is connected to an associated bit line BL, and a source of the select transistor ST(1) is connected to one end of the memory cell transistors MT(0) to MT(15) connected in series. A drain of the select transistor ST(2) is connected to the other end of the memory cell transistors MT(0) to MT(15) connected in series. A source of the select transistor ST(2) is connected to a source line SL.

In the same block BLK, control gates of the memory cell transistors MT(0) to MT(15) are connected in common to word lines WL(0) to WL(7), respectively. Gates of the select transistors ST(1) in the string units SU(0) to SU(k) are connected to select gates SGD(0) to SGD(k), respectively. Gates of the select transistors ST(2) are connected in common to a select gate line SGS.

In the circuit configuration of the memory cell array 10 described above, each bit line BL is shared by the NAND strings NS to which a same column address is allocated in each string unit SU. The source line SL is shared among all blocks BLK, for example.

A set of memory cell transistors MT connected to a common (same) word line WL in the same string unit SU can be referred to as a cell unit CU. For example, a storage capacity of the cell unit CU including the memory cell transistors MT each storing 1-bit data is defined as “1-page data”. The cell unit CU may have the storage capacity of 2-page data or more according to the number of bits of data that can be stored in each memory cell transistor MT.

Note that a memory cell array 10 provided in a semiconductor memory device 100 according to the present embodiment is not limited to the circuit configuration described above. For example, the numbers of the memory cell transistors MT and/or the select transistors ST(1) and ST(2) included in each NAND string NS may be varied from that depicted. Likewise, the number of the string units SU included in each block BLK may be selected to be an arbitrary number.

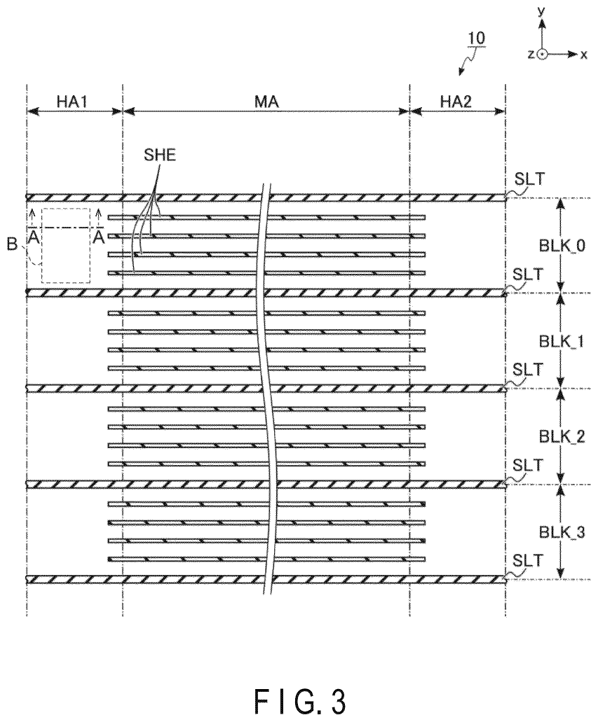

FIG. 3 is a plan view illustrating an example of a planar layout of a part of the memory cell array 10 of the semiconductor memory device 100 according to the first embodiment. FIG. 3 illustrates a region in which four blocks BLK (BLK_0 to BLK_3) are formed along an xy plane. The structure illustrated in FIG. 3 may be repeatedly provided along a y axis direction, for example.

As illustrated in FIG. 3, the memory cell array 10 includes a memory region MA, a lead-out region HA1, and a lead-out region HA2. The lead-out region HA1, the memory region MA, and the lead-out region HA2 are arranged in this order along an x axis. The memory cell array 10 is provided with slits SLT and slits SHE.

The memory region MA is a region including the plurality of NAND strings NS. The lead-out region HA1 and the lead-out region HA2 are regions provided for contact plugs connected to the stacked, multiple level/layer structure in which the memory cell transistors are formed.

The slits SLT extend lengthwise along the x axis and are arranged with respect to each other along the y axis. Each slit SLT is located at a boundary between a pair of adjacent blocks BLK. The slit SLT crosses the memory region MA, the lead-out region HA1, and the lead-out region HA2. The slit SLT has can be an entirely insulating structure or may incorporate a plate-shaped conductor embedded therein. Each slit SLT divides stacked structures that are adjacent to each other via itself.

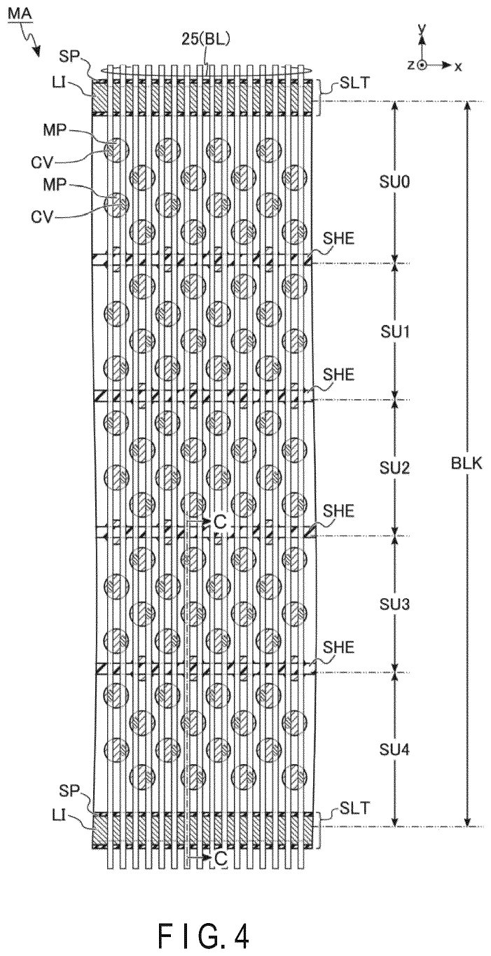

The slits SHE extend lengthwise along the x axis and are arranged with respect to each other along the y axis. Each slit SHE is located between an adjacent pair of slits SLT. FIG. 4 illustrates an example of four slits SHE in a block BLK. Each slit SHE crosses the memory region MA along the x axis. The ends of each slit SHE are located in the lead-out region HA1 and the lead-out region HA2, respectively. Each slit SHE comprises an insulator. Each slit SHE divides select gate lines SGDL that are adjacent to each other via itself. Each region divided by the slit SLT and the slit SHE is a region in which one string unit SU is formed.

FIG. 4 is a plan view illustrating an example of a planar layout of a part of the memory region MA of the semiconductor memory device 100 according to the first embodiment. FIG. 4 illustrates the two slits SLT sandwiching a block BLK, with the region therebetween including string units SU0 to SU4. As illustrated in FIG. 4, the memory cell array 10 includes a plurality of memory pillars MP, a plurality of contact plugs CV, and a plurality of conductors 25 in the memory region MA. In this example, each slit SLT includes a contact LI therein with a spacer SP thereon.

The memory cell transistors MT are formed with the structure of memory pillar MP. The memory pillar MP is an example of a second pillar. The memory pillar MP includes one or more of a semiconductor, a conductor, and an insulator. Each memory pillar MP functions as one NAND string NS. The plurality of memory pillars MP are distributed in a staggered arrangement in the region between the two slits SLT. That is, the memory pillars MP are arranged in a plurality of columns along the y axis. The columns have memory pillars MP that are arrayed in zigzags along the y axis. In other words, each column includes two sub-columns. A coordinate on the y axis of each memory pillar MP in one of the sub-columns is located at a coordinate on the y axis between two adjacent memory pillars MP in the other sub-column. Each column includes, for example, 24 memory pillars MP.

In each column, slits SHE overlap, for example, the fifth, tenth, fifteenth, and twentieth memory pillars MP as counted from the top of FIG. 4.

Each conductor 25 functions as one bit line BL. The conductors 25 extend along the y axis and are arranged with respect to each along the x axis. Each conductor 25 is arranged so as to overlap at least one memory pillar MP for each string unit SU. FIG. 4 illustrates an example in which two conductors 25 overlap each memory pillar MP. However, each memory pillar MP is electrically connected (via the contact plug CV) to just one conductor 25 of the conductors 25 overlapping the memory pillar MP.

The contact LI includes a conductor. The contact LI extends along an xz plane and has a plate-like shape. The spacer SP is an insulator and is located on a side face of the contact LI. For example, the spacer SP covers the side faces of the contact LI.

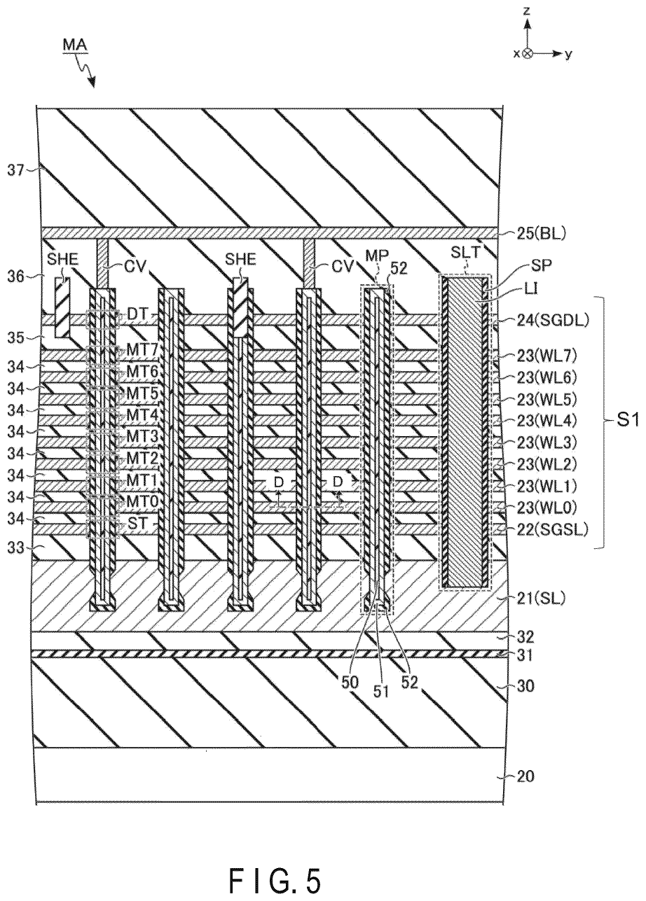

FIG. 5 is a cross-sectional view of a part of the memory region MA of the semiconductor memory device 100 according to the first embodiment. FIG. 5 is a cross-sectional view along a line CC in FIG. 4.

As illustrated in FIG. 5, the memory cell array 10 includes a substrate 20, a conductor 21, a conductor 22, a plurality of conductors 23, a conductor 24, a conductor 25, an insulator 30, an insulator 31, an insulator 32, an insulator 33, a plurality of insulators 34, an insulator 35, an insulator 36, and an insulator 37. FIG. 5 illustrates an example with eight conductors 23 (eight word lines WL). Except for the insulator 31, the insulators 30 to 37 may each be silicon oxide, for example.

The substrate 20 is, for example, a p-type semiconductor substrate. The insulator 30 is located on an upper surface of the substrate 20. A peripheral circuit or the like can be formed in the substrate 20 and the insulator 30. Such a circuit can be, for example, the command register 1011, the address register 1012, the sequencer 1013, the driver module 1014, the row decoder module 1015, and/or the sense amplifier module 1016. Such circuits/components generally comprise transistors.

The insulator 31 is located on an upper surface of the insulator 30. For example, the insulator 31 suppresses penetration of hydrogen into the circuit transistors formed in the substrate 20 and the insulator 30 from the structure above the insulator 31. The insulator 31 is, for example, silicon nitride (SiN).

The insulator 32 is located on an upper surface of the insulator 31.

The conductor 21 is located on an upper surface of the insulator 32. The conductor 21 extends along the xy plane and has a plate-like shape. The conductor 21 functions as a part of the source line SL. The conductor 21 comprises, for example, silicon doped with phosphorus (P).

The insulator 33 is located on an upper surface of the conductor 21.

The conductor 22 is located on an upper surface of the insulator 33. The conductor 22 extends along the xy plane and has a plate-like shape. The conductor 22 functions as a part of the select gate line SGSL. The conductor 22 comprises, for example, tungsten (W).

The plurality of insulators 34 and the plurality of conductors 23 are alternately located one by one along a z axis (stacking direction) upon an upper surface of the conductor 22. The insulators 34 are an example of first insulating films, and the conductors 23 are an example of first conductive films. The z axis is an example of a first direction. A stacked body S1 is formed by alternately stacking the plurality of insulators 34 and the plurality of conductors 23 along a z axis direction. The stacked body S1 is an example of a first stacked body. In the stacked body S1, the conductors 23 are separated from each other along the z axis. The insulators 34 and the conductors 23 extend along the xy plane and have a plate-like shape. The plurality of conductors 23 function as the word lines WL0 to WL7 (numbering in order from the substrate 20). The conductors 23 comprise, for example, tungsten.

The insulator 35 is located on an upper surface of the uppermost conductor 23.

The conductor 24 is located on an upper surface of the insulator 35. The conductor 24 extends along the xy plane and has a plate-like shape. The conductor 24 functions as a part of the select gate line SGDL. The conductor 24 comprises tungsten.

The insulator 36 is located on an upper surface of the conductor 24.

The conductors 25 are located on an upper surface of the insulator 36. Each conductor 25 has a linear shape and extends lengthwise along a y axis direction. Each conductor 25 functions as a bit line BL. Multiple conductors 25 are arranged at intervals along the x axis as illustrated in FIG. 4. The conductors 25 comprise, for example, copper.

The insulator 37 is located on an upper surface of the conductor 25.

Each memory pillar MP extends along the z axis direction and has a pillar (columnar) shape. The memory pillar MP is an example of a second pillar. The memory pillar MP extends in the z axis direction through the stacked body S1. An upper surface (end) of the memory pillar MP is located above the level of conductor 24. A lower surface (ed) of the memory pillar MP is located in the conductor 21. A portion where the memory pillar MP contacts conductor 22 functions as a select gate transistor ST. The portion where the memory pillar MP contacts each conductor 23 functions as one memory cell transistor MT. The portion where the memory pillar MP and the conductor 24 contact each other functions as a select transistor DT.

The memory pillar MP comprises, for example, a core 50, a semiconductor layer 51, and a layered body 52. The core 50 is made of an insulator and comprises, for example, silicon oxide. The core 50 extends along the z axis direction and has a pillar shape. The semiconductor layer 51 comprises, for example, silicon. The semiconductor layer 51 is an example of a first semiconductor portion. The semiconductor layer 51 covers a surface of the core 50. The layered body 52 covers a side face and a lower surface of the semiconductor layer 51. The layered body 52 is an example of a first insulator portion. The layered body 52 has an opening at position inside the conductor 21 through which the conductor 21 extends. The conductor 21 and the semiconductor layer 51 are thus in contact with each other in the opening.

As described above, one memory pillar MP and one conductor 25 are connected to each other by one contact plug CV.

The slit SLT divides the conductors 22, 23, 24. An upper surface of the slit SLT is located at a level above the level of the upper surface (upper end) of the memory pillar MP. A lower surface of the contact LI is in contact with the conductor 21. The spacer SP is located between the contact LI and the conductors 22, 23, 24, and insulates the contact LI from the conductors 22, 23, 24. The contact LI functions as a part of the source line SL.

The slit SHE divides just the conductor 24. A lower surface of the slit SHE is positioned in the insulator 35. The slit SHE comprises, for example, an insulator such as silicon oxide.

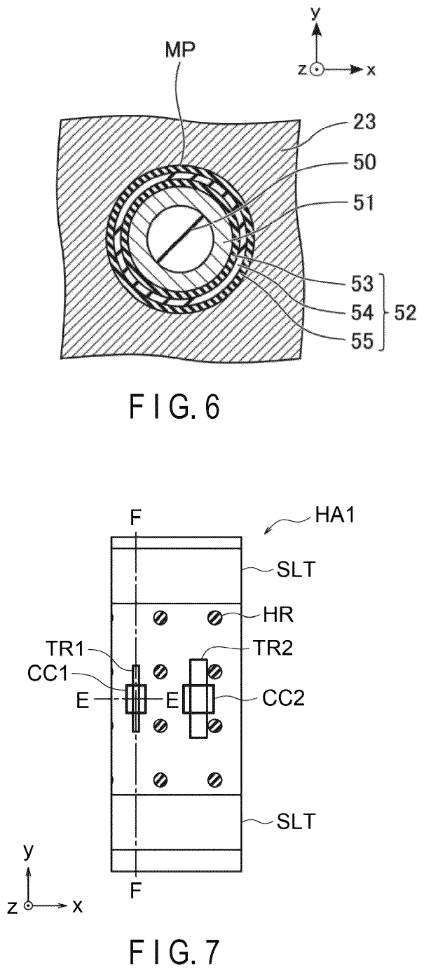

FIG. 6 illustrates a cross-sectional structure of a memory pillar MP of the semiconductor memory device 100 according to the first embodiment. FIG. 6 illustrates a cross section along a line DD in FIG. 5. As illustrated in FIG. 6, the layered body 52 includes, for example, a tunnel insulating film 53, a charge storage film 54, and a block insulating film 55.

The tunnel insulating film 53 covers an outer periphery of the semiconductor layer 51. The charge storage film 54 covers an outer periphery of the tunnel insulating film 53. The block insulating film 55 covers an outer periphery of the charge storage film 54. The conductor 23 surrounds an outer periphery of the block insulating film 55.

The semiconductor layer 51 functions as a channel (current path) of the memory cell transistors MT0 to MT7 and the select transistors DT and ST. Each of the tunnel insulating film 53 and the block insulating film 55 comprises, for example, silicon oxide. The charge storage film 54 stores charges. The charge storage film 54 comprises, for example, silicon nitride. (Description of Support Pillars HR and Contact Plugs CC)

FIG. 7 is a plan view illustrating a positional relationship of the support pillars HR, trenches TR, and the contact plugs CC in a lead-out region HA1. FIG. 7 is a plan view obtained by enlarging the region B depicted in FIG. 3.

Trenches TR1 and TR2 and contact plugs CC1 and CC2 in FIG. 7 can each have configurations of different sizes. The trenches TR1 and TR2 may be collectively referred to as trenches TR, and the contact plugs CC1 and CC2 may be collectively referred to as contact plugs CC.

The contact plugs CC are provided so as to extend along the z axis direction. The contact plug CC is an example of a first pillar. The contact plugs CC are provided, for example, at positions between adjacent support pillars HR. The contact plugs CC and the support pillars HR may be in contact with each other or separated from each other. Any number of contact plugs CC may be provided in the lead-out region HA1.

In the plan view from the z direction in FIG. 7, the shape of each contact plug CC is substantially rectangular. However, the shape of the contact plug CC is not limited to being substantially rectangular. In other examples, the shape may be substantially circular, substantially elliptic, or otherwise.

The support pillars HR extend along the z axis direction. The support pillar HR functions as a support column that suppresses the collapse of the stacked body S1 (memory cell array 10) during a replacement process which is an intermediate step of the manufacturing process for memory cell array 10. Therefore, the support pillars HR are required to be provided at some predetermined interval or less to prevent physical collapses during manufacturing. The support pillar HR has a pillar (columnar) shape and extends along the z axis from the insulator 36 to the conductor 21. The support pillar HR comprises, for example, an insulator such as silicon oxide. Any number of support pillars HR may be provided in the lead-out region HA1.

As illustrated in FIG. 7, the support pillars HR are provided at regular intervals over the entire lead-out region HA1. These support pillars HR each have a substantially circular planar shape.

Each trench TR is a groove that extends in the z axis direction from a bottom surface of the stacked body S1. The trench TR is provided so as to overlap at least in part with respective contact plugs CC in plan view from the z direction.

In plan view from the z direction, a shape of the trench TR is, for example, substantially rectangular. However, a shape of the contact plug viewed from the z direction is not limited to being substantially rectangular.

While FIG. 7 depicts the support pillars HR, the trenches TR, and the contact plugs CC in the lead-out region HA1 in FIG. 3, the support pillars HR, the trenches TR, and the contact plugs CC are configured similarly in the lead-out region HA2 as well.

### Method of Manufacturing Semiconductor Memory Device 100

Next, a method of manufacturing the semiconductor memory device 100 will be described.

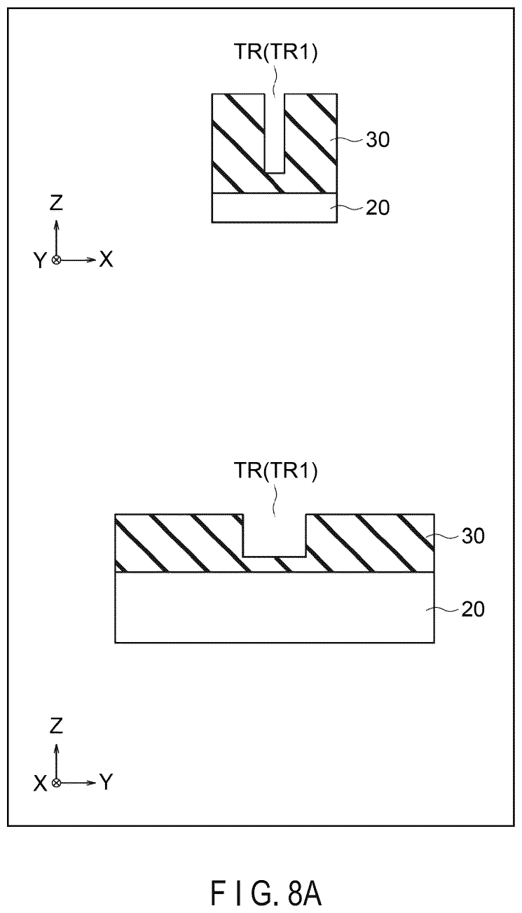

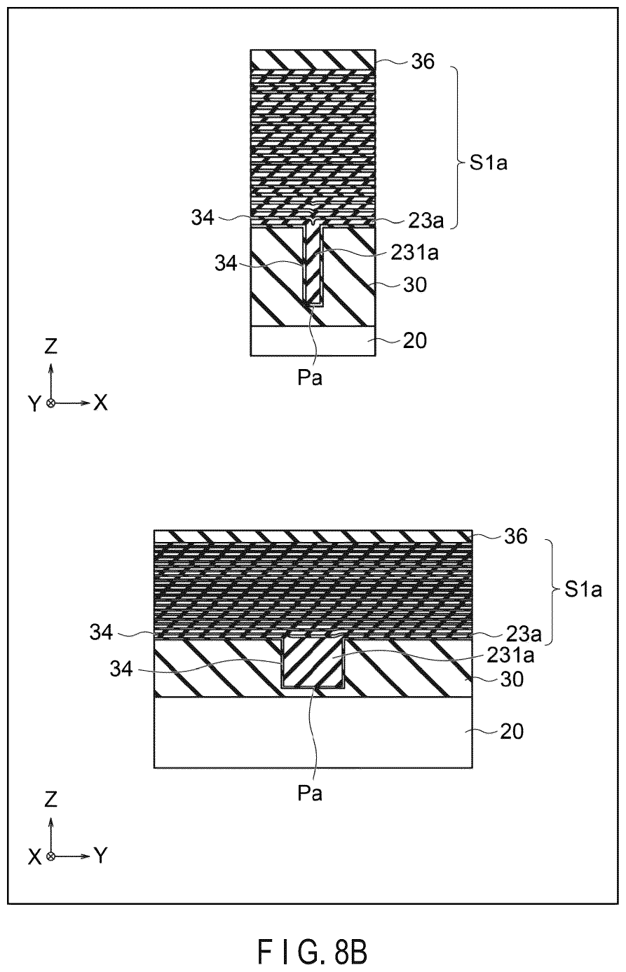

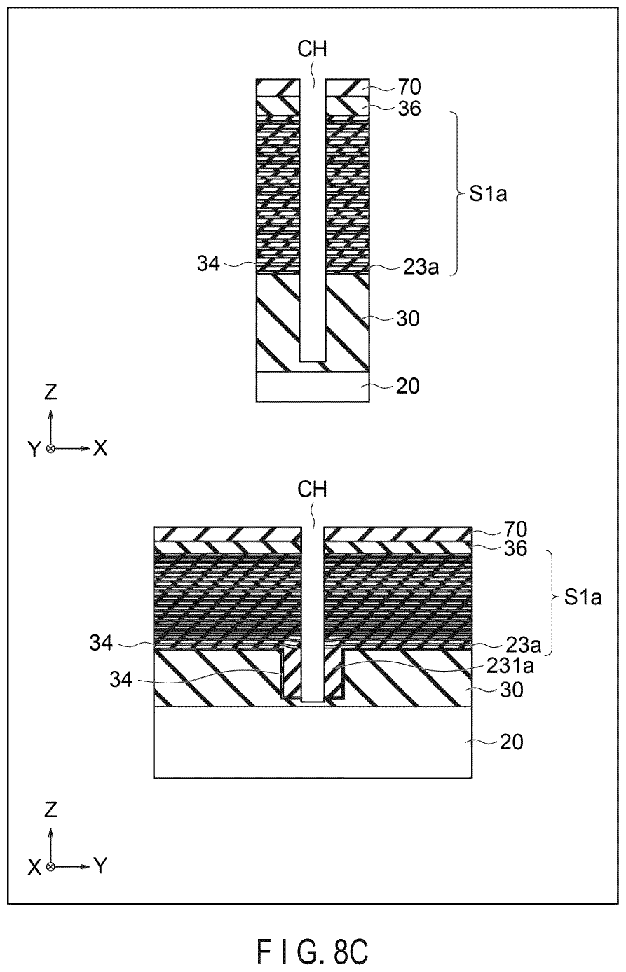

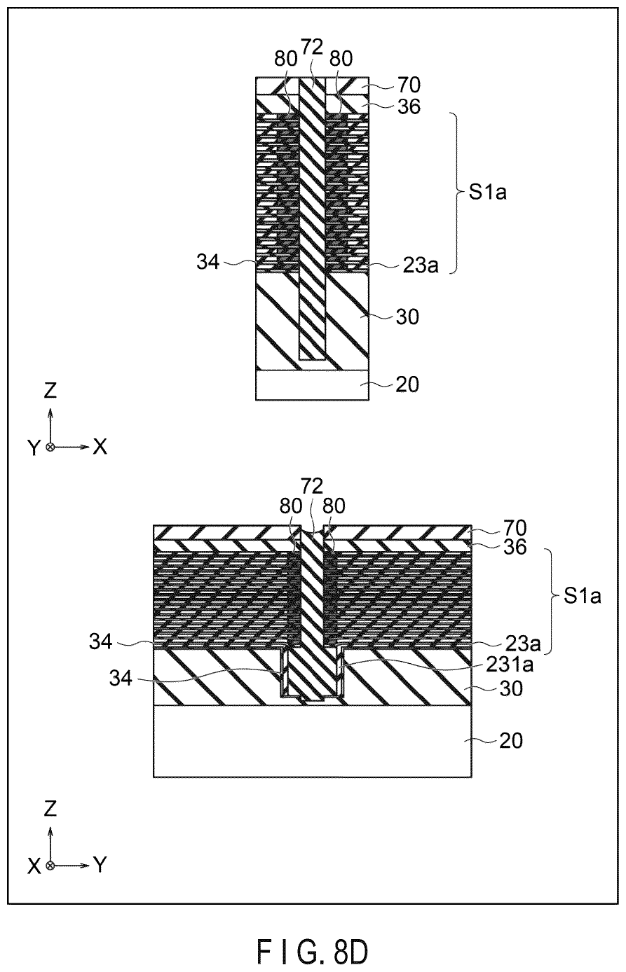

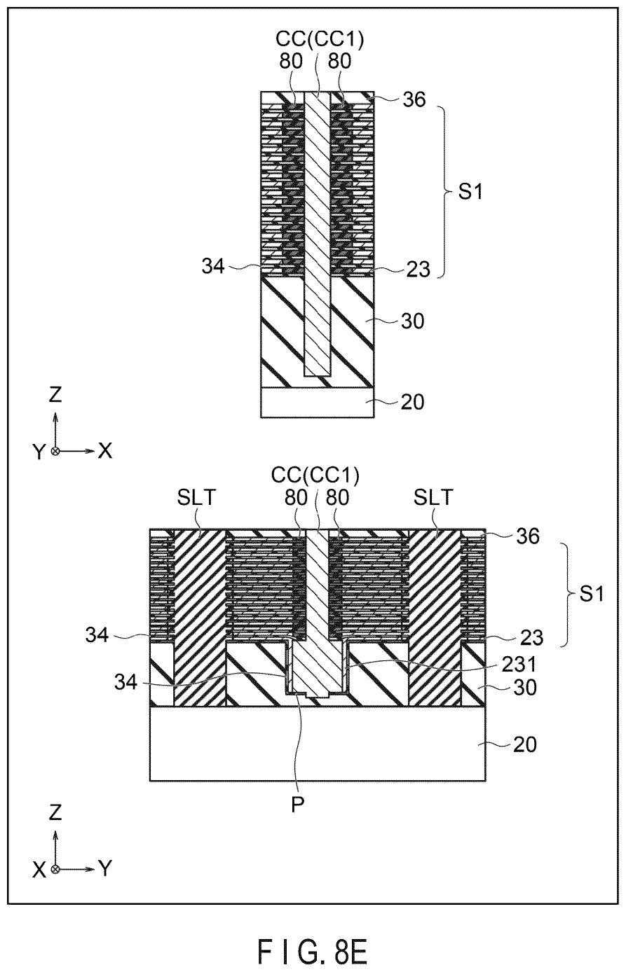

FIG. 8A to FIG. 8E depict processes in the method of manufacturing the semiconductor memory device 100 according to the first embodiment. Upper portions of FIG. 8A to FIG. 8E illustrate a cross section (a short dimension of the trench TR) along a line EE in FIG. 7, and lower portions of FIG. 8A to FIG. 8E illustrate a cross section (a long dimension of the trench TR) along a line FF in FIG. 7.

First, as illustrated in FIG. 8A, the insulator 30 is formed on the substrate 20. The insulator 30 is an example of a third insulating film. Thereafter, the trench TR (e.g., trench TR1) is formed in the insulator 30. The substrate 20 is, for example, a semiconductor substrate such as a silicon substrate.

Next, as illustrated in FIG. 8B, on the insulator 30 and in the trench TR, a stacked body S1a obtained by alternately stacking sacrificial films 23a and the insulators 34 in the z axis direction is formed. Thereafter, the insulator 36 is formed on the stacked body S1a. A silicon oxide film can be used for the insulators 34 and 36, and a silicon nitride film can be used for the sacrificial films 23a.

At least one insulator 34 layer and at least one sacrificial film 23a are stacked on each other inside the trench TR. Depending on the dimensions of the trench TR, multiple insulator 34 layers and sacrificial films 23a may be present inside the trench TR. As depicted in FIG. 8A, a part of a sacrificial film 23a closes (fills) the upper end of the trench TR at the level of the upper surface of the insulator 30. The sacrificial film 23a that closes the upper end of the trench TR is referred to as a joining portion 231a. In the trench TR, the joining portion 231a has a width dimension different from the standard width/thickness of the sacrificial films 23a. A protruding portion Pa of the stacked body S1a is formed protruding from the stacked body S1a into the insulator 30 according to the shape/dimensions of the trench TR.

Next, as illustrated in FIG. 8C, a contact hole CH for the contact plug CC is formed. The contact hole CH passes through the stacked body S1a and the joining portion 231a inside the trench TR1. More specifically, in this process, a hard mask 70 is formed on the insulator 36. The hard mask 70 may be, for example, silicon nitride. Thereafter, the hard mask 70 is used as an etch mask and a contact hole CH passing through the stacked body S1a in the z direction is formed by lithography followed by anisotropic etching such as RIE (Reactive Ion Etching).

As illustrated in the upper stage of FIG. 8C, a width (in an x direction) of the contact hole CH is larger than a width (in the x direction; the dimension of the short side depicted in the upper portion FIG. 8C) of the trench TR. As illustrated in the lower portion of FIG. 8C, the width (in a y direction) of the contact hole CH is smaller than the width (in the y direction; the dimension of the long side depicted in the lower portion of FIG. 8C) of the trench TR.

Next, as illustrated in FIG. 8D, portions of the sacrificial films 23a are removed (recessed) from an inner side face (sidewall) of the contact hole CH. Thus, a portion of the sacrificial films 23a is removed. In particular, ends of the sacrificial films 23a facing the contact hole CH are recessed from the sidewall of the contact hole CH.

In the lower portion of FIG. 8D, the sacrificial film 23a in the lowermost layer is recessed more than the sacrificial films 23a in the layers other than the lowermost layer.

Thereafter, an insulator 80 (spacer) is formed on the inner side face of the contact hole CH. The insulator 80 is an example of a second insulating film. For the insulator 80, silicon oxide can be used. The recessed parts of the sacrificial films 23a in the layers other than the lowermost layer are embedded (filled) with the insulator 80 and closed. The recessed part of the sacrificial film 23a in the lowermost layer is not fully closed though the insulator 80 may be formed on the exposed surfaces thereof.

Then, a part of the previously deposited insulator 80 is removed by an etch back process. A part of the insulator 80 is removed by, for example, wet etching. More specifically, some of the insulator 80 is removed to expose the joining portion 231a. In general, at least some of the insulator 80 embedded in the recessed portions of the sacrificial films 23a in the layers other than the lowermost layer remains without being totally removed. On the other hand, the insulator 80 on the sacrificial film 23a in the lowermost layer is totally removed. Thus, after this process, the joining portion 231a is not covered by the insulator 80 and is thus exposed on the side face of the contact hole CH.

Thereafter, a sacrificial film 72 is embedded inside the contact hole CH and is then etched back from the upper surface of hard mask 70. For the sacrificial film 72, amorphous silicon is used, for example.

Next, as illustrated in FIG. 8E, the slits SLT are formed. Thereafter, the sacrificial films 23a are removed then replaced by the conductors 23 (the word lines WL) via the slits SLT. Since the lowermost sacrificial film 23a is continuous with the joining portion 231a, the joining portion 231a can become a joining portion 231, formed of the material of the lowermost conductor 23, after the replacement process. Then, the contact plug CC is formed by removing and replacing the sacrificial film 72 with a conductor material. The contact plug CC can contact the joining portion 231 and thus be electrically connected to the joining portion 231. Thereafter, flattening (planarization) is performed. Note that the slits SLT are embedded (filled) after the replacement of the conductors 23. Then, the semiconductor memory device 100 is completed by additional conventional processes.

The processes illustrated in FIGS. 8A to 8E are performed not only on the trench TR1 but also at the same time on the plurality of trenches TR. In the process illustrated in FIG. 8A, since trenches TR (for example, the trenches TR1 and TR2 illustrated in FIG. 7) having different widths are provided, they can be positioned and sized such that the closing sacrificial film 23a (that is, the last sacrificial film 23a to include a portion inside the trench TR so as to be the one to form the joining portion 231a) can be different sacrificial films 23a (that is, by varying trench TR dimensions, sacrificial films 23a at different levels/layers in the stacked body S1 can form the joining portion 231a).

As illustrated in FIG. 7, the plurality of contact plugs CC1 and CC2 may also have different widths in the direction crossing the z direction. In the process illustrated in FIG. 8C, the plurality of contact holes CH are formed such that at least a part of an outer edge of the joining portion 231a goes beyond an outer edge of the contact hole CH when viewed from the z direction.

While the two trenches TR1 and TR2 are illustrated in FIG. 7, any number of trenches may be formed. By forming the trenches TR with different widths like the trenches TR1 and TR2, contact plugs CC electrically connected to each of the plurality of conductors 23 can be formed using a single photolithography process, such as a photo engraving process (PEP).

The semiconductor memory device 100 includes the stacked body S1 and the plurality of contact plugs CC. The contact plugs CC extend in the z direction and pass through the stacked body S1. Each of the contact plugs CC is a conductor electrically connected to just one of the conductors 23 in the stacked body S1. The stacked body S1 includes a plurality of protruding portions P that protrude downward in the z direction according to the shape of the plurality of trenches TR that are formed. Each contact plug CC passes through the joining portion 231 formed from one conductor 23 inside a trench TR. The contact plug CC is thus electrically connected to the one conductor 23 that is continuous with the joint portion 231 in the particular trench TR.

For each contact plug CC, the film thickness of the conductor 23 forming the joining portion 231 is greater than the film thickness of the other conductors 23. The joining portion 231 is an integral part of the one conductor 23 (the last conductor 23 inside the trench TR) that closes the trench TR. In addition, the joining portion 231 is provided in the center portion (middle) of the trench TR.

Since the plurality of trenches TR have different widths the trenches TR close with the different conductors 23 (that is, at different conductor 23 levels of the stacked body S1).

The contact plug CC may have a substantially elliptic or substantially rectangular shape when viewed from the z direction. The contact plug CC and the trench TR may have a substantially rectangular shape when viewed from the z direction. In this case, when viewed from the z direction, a one side of the contact plug CC may be longer than a short side of the joining portion 231. Preferably, at least a part of the outer edge of the joining portion 231 exceeds (extends beyond) the outer edge of the contact plug CC when viewed from the z direction.

The first embodiment may be applied not only to the semiconductor memory device 100 but also to a semiconductor device in which a contact to stacked electrodes is formed or the like.

As described above, according to the first embodiment, the stacked body S1 includes the plurality of protruding portions P protruding in the z direction according to the shape of the plurality of trenches TR below the stacked body S1. Each contact plug CC passes through the joining portion 231 of the conductor 23 inside a trench TR and is electrically connected to a conductor 23 thereby. Thus, the number of processes for forming the contact plugs CC can be reduced since each of the different trenches TR can be formed in the same process step.

In the process illustrated in FIG. 8C, the contact hole CH is formed so as to pass through a part of the joining portion 231a of the sacrificial film 23a. In the process illustrated in FIG. 8C, the contact hole CH is formed such that at least a part of the outer edge of the joining portion 231a is beyond the outer edge of the contact hole CH. Thus, the joining portion 231 (formed by the replacement of joining portion 231a) and the contact plug CC are in contact with each other. As a result, the joining portion 231 and the contact plug CC are electrically connected to each other.

In the process illustrated in FIG. 8B, the width of the short side (the width in the x direction) of the trench TR is adjusted such that the trench TR is closed by the lowermost sacrificial film 23a and the joining portion 231a is formed therefrom. However, by changing the width of the short side of the trench TR, an electrical connection to any word line WL (conductor 23) among the word lines WL0 to WL7 (conductors 23 in stacked body S1) can be formed. For example, the trench TR2 illustrated in FIG. 7 has a width different from the trench TR1. Thus, trench TR2 can be closed by the sacrificial film 23a in a layer one above the lowermost layer, for example.

Therefore, by forming a plurality of trenches TR having different widths in one photolithography process, the plurality of contact plugs CC each connected to a different one of the plurality of conductors 23 can be more easily formed.

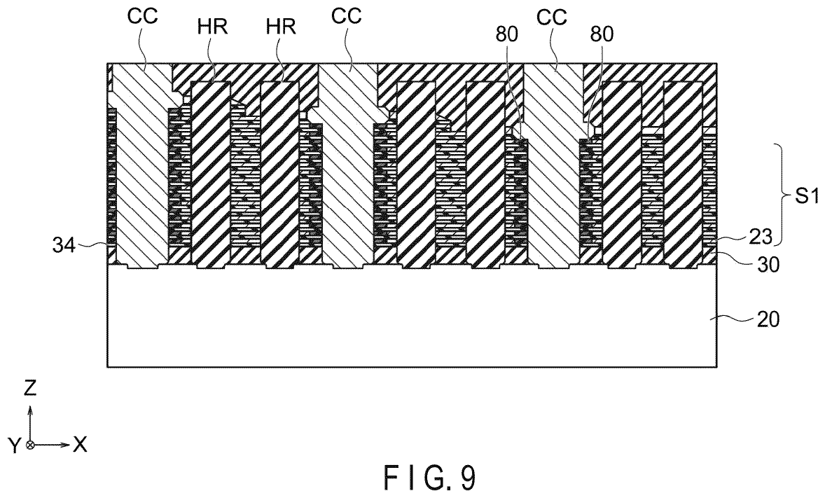

FIG. 9 is a cross-sectional view illustrating a part of a lead-out region of a semiconductor memory device according to a comparative example. The comparative example differs from the first embodiment in that a staircase structure is formed in the stacked body S1 and connections to different levels in the stacked body S1 are formed by contact plugs CC at each staircase level of the stacked body S1.

The comparative example requires processes of forming the staircase structure in the stacked body S1, increasing the thickness of the sacrificial films 23a at the ultimate connection points of the conductor 23 to the contact plug CC, embedding (covering) the staircase structure, and performing flattening (CMP). In this case, the number of processes is greater and it is difficult to reduce costs.

In contrast, the first embodiment does not require a process corresponding to formation of the staircase structure or a process corresponding to increasing (thickening) of a sacrificial film 23a to be replaced with the conductor 23. As a result, the number of processes can be reduced. In addition, the arrangement density of the contact plug CC can be increased. As a result, the size (area) of lead-out regions HA1 and HA2 can be reduced.

### Second Embodiment

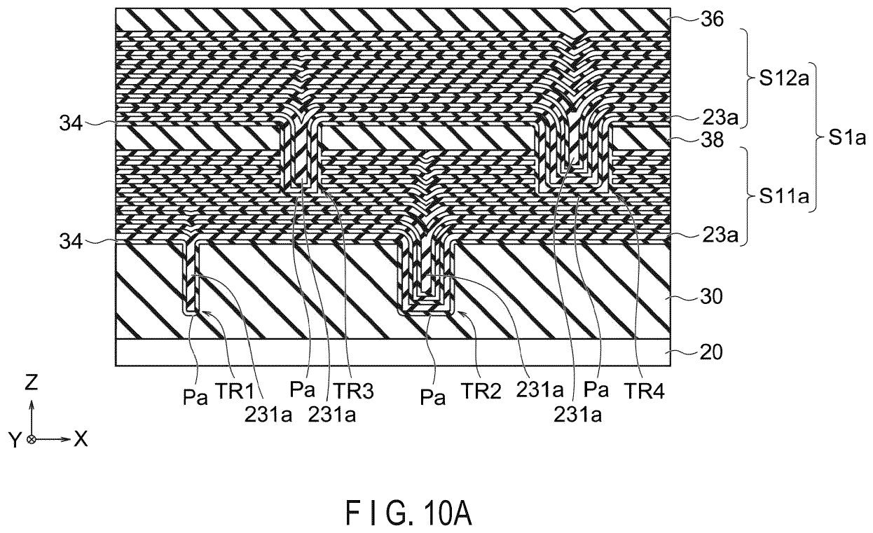

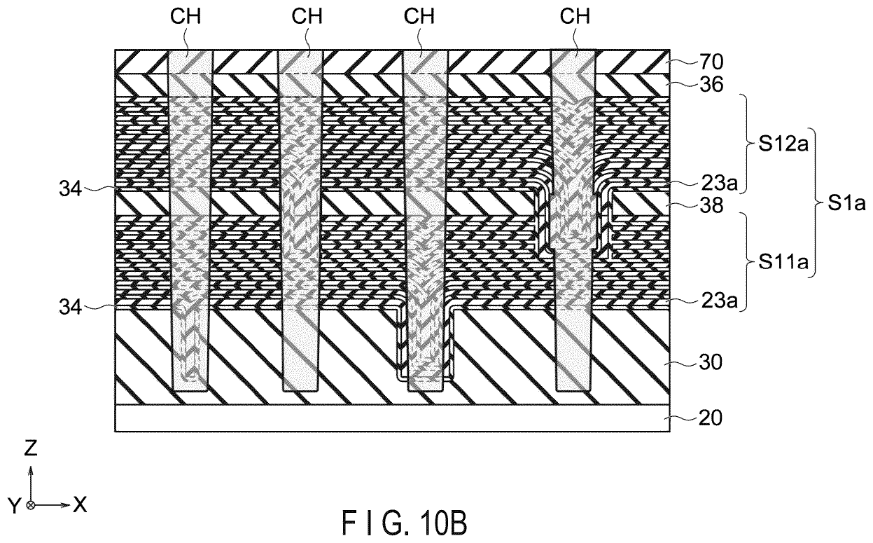

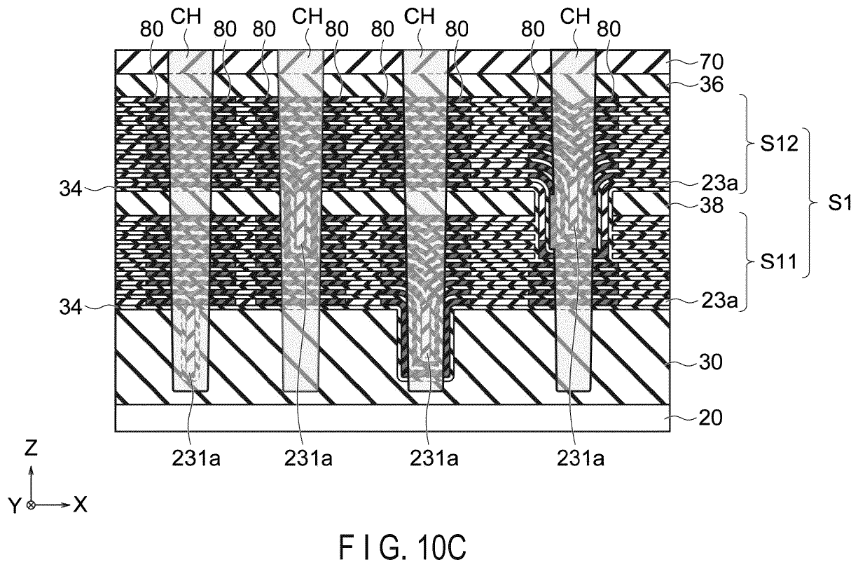

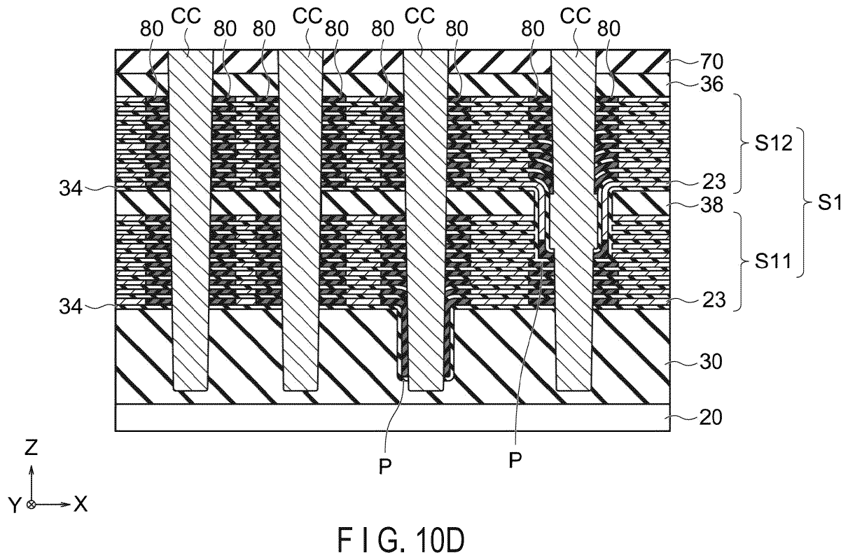

FIG. 10A to FIG. 10D depict processes of a method of manufacturing the semiconductor memory device 100 according to the second embodiment. The second embodiment differs from the first embodiment in that the trenches TR can also be provided in the stacked body S1 (the stacked body S1a). Note that FIG. 10B and FIG. 10C illustrate a portion of the stacked body S1a behind the contact hole CH with broken lines.

In FIG. 10A to FIG. 10D, the overall stacked body S1a is divided into two stacked bodies S11a and S12a. The stacked body S12a is provided above the stacked body S11a.

First, as illustrated in FIG. 10A, the insulator 30 is formed on the substrate 20. Thereafter, the trenches TR1 and TR2 are formed in the insulator 30. Then, a stacked body S11a obtained by alternately stacking the sacrificial films 23a and the insulators 34 in the z axis direction is formed on the insulator 30 and inside the trenches TR1 and TR2. Thereafter, an insulator 38 is formed on the stacked body S11a. A material of the insulator 38 is, for example, the same material as that of the insulator 36. Then, trenches TR3 and TR4 are formed in the insulator 38 and in the stacked body S11a. The trenches TR3 and TR4 are formed at positions different from positions of the trenches TR1 and TR2 on the xy plane. Thereafter, a stacked body S12a obtained by alternately stacking the sacrificial films 23a and the insulators 34 in the z axis direction is formed on the insulator 38 and inside the trenches TR3 and TR4. The trenches TR3 and TR4 are grooves that extend in the z axis direction from a bottom surface of the stacked body S12a. Note that, in some examples, the insulator 38 need not be formed. In such a case, the stacked body S12a is formed directly on the stacked body S11a.

In FIG. 10A, a joining portion 231a of the sacrificial film 23a in the lowermost layer of the stacked body S11a is formed inside the trench TR1. A joining portion 231a of the sacrificial film 23a in the layer third from the bottom of the stacked body S11a is formed inside the trench TR2. A joining portion 231a of the sacrificial film 23a in the layer second from the bottom of the stacked body S12a is formed inside the trench TR3. A joining portion 231a of the sacrificial film 23a in the layer fourth from the bottom of the stacked body S12a is formed inside the trench TR4.

Next, as illustrated in FIG. 10B, the contact holes CH for the contact plugs CC are formed. The plurality of contact holes CH pass through the joining portions 231a inside the trenches TR. The method of forming the contact holes CH is similar to the process illustrated in FIG. 8C in the first embodiment.

As illustrated in FIG. 10C, portions of the sacrificial films 23a are removed (recessed) from the inner side face (sidewall) of the contact holes CH. Thereafter, the insulator 80 (spacer) is formed on the inner side face of the contact holes CH. Then, a part of the insulator 80 is etch backed.

As illustrated in FIG. 10C, the joining portions 231a are not covered by the insulator 80. The joining portions 231a are thus exposed at the side face of the contact holes CH.

In a manner similar to FIG. 8D, the sacrificial film 72 is embedded inside the contact holes CH and is then etched back. Thereafter, the slits SLT are formed. Then, the sacrificial films 23a are replaced with the conductors 23 (the word lines WL) via the slit SLT. The joining portion 231a becomes the joining portion 231 of a conductor 23 after the replacement. Thereafter, as illustrated in FIG. 10D, the contact plug CC is formed by replacing the sacrificial film 72 with a conductor material. Each contact plug CC is electrically connected to a joining portion 231. Thereafter, flattening (planarization) is performed so as to expose the hard mask 70.

In general, as the number of the stacked conductors 23 increases, the width of the short side of the trenches TR to be formed also needs to be gradually increased. By dividing a stacked body S1 into a plurality of stacked bodies (e.g., stacked bodies S11 and S12) and then forming the trenches TR for each of the stacked bodies S11 and S12 respectively, the width of the short side of the trench TR corresponding to an upper layer portion of the stacked body S1 can be reduced. For example, the width in the x direction of the trench TR3 illustrated in FIG. 10A is smaller than the width in the x direction of the trench TR2. Thus, the size of lead-out regions HA1 and HA2 can be reduced.

The number of subdivisions of the stacked body S1 is not limited to two. By increasing the number of subdivisions of the stacked body S1, the required width of the trench TR can be reduced. However, when the number of divisions is increased, the number of photolithography processes for forming trenches TR (PEP number) increases since each subdivision requires a separate photolithography process for forming the respective trenches TR. Therefore, the number of subdivisions of the stacked body S1 may be determined in consideration of area limitations and the desired maximum number of processes.

Note that the trench TR below the stacked body S1 (the stacked body S1a) may not be provided. However, for the contact of a lower layer portion of the stacked body S1, the trench TR below the stacked body S1 (the stacked body S1a) may be provided.

As in the second embodiment, the trench TR may be provided in the stacked body S1 (the stacked body S1a). The semiconductor memory device 100 by the second embodiment can obtain effects similar to those of the first embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor device, comprising:
a first stacked body on an insulator layer, the first stacked body including alternating first insulating films and first conductive films stacked one upon the other in a first direction; and
a plurality of first pillars that extend in the first direction and pass through the first stacked body, each first pillar being electrically connected to only a respective one of the first conductive films in the first stacked body, wherein the first stacked body has protruding portions extending into the insulator layer, and
each first pillar passes through a joining portion of the respective one of the first conductive films inside a trench in the insulator layer corresponding in position with a protruding portion, the first pillar being electrically connected to the respective one of the first conductive films via the joining portion.

2. The semiconductor device of claim 1, wherein
a film thickness of the joining portion of the respective one of the first conductive films is greater than a film thickness of the other first conductive films in the protruding portion.

3. The semiconductor device of claim 1, wherein the respective one of the first conductive films is the one that closes the trench.

4. The semiconductor device of claim 1, wherein the joining portion is in a center portion of the trench.

5. The semiconductor device of claim 1, wherein the protruding portions have different widths in a direction crossing the first direction.

6. The semiconductor device of claim 1, wherein the first pillar has a substantially elliptic shape when viewed from the first direction.

7. The semiconductor device of claim 1, wherein the first pillar has a substantially rectangular shape when viewed from the first direction.

8. The semiconductor device of claim 1, wherein
each first pillar and each trench has a substantially rectangular shape when viewed from the first direction, and
a long side of the first pillar is longer than a short side of the joining portion when viewed from the first direction.

9. The semiconductor device of claim 1, wherein at least a part of an outer edge of the joining portion extends beyond an outer edge of the first pillar when viewed from the first direction.

10. The semiconductor device of claim 1, further comprising:
a memory pillar extending in the first direction in the first stacked body.

11. A memory device, comprising:
an insulator layer;
a memory cell array on the insulator layer and including a stacked body of a plurality of insulating films alternatingly stacked with a plurality of conductor films, protruding portions of the stacked body extending in a first direction into the insulator layer, the protruding portions including at least some of the alternatingly stacked insulating films and conductor films;
a plurality of memory pillars extending in the first direction through the stacked body in a memory cell region of the memory cell array; and
a plurality of contact pillars extending in the first direction through the stacked body into the protruding portions and the insulator layer, the contact pillars being in a lead-out region of the memory cell array adjacent to the memory cell region, wherein
each contact pillar is electrically connected to a different conductive film in the stacked body.

12. The memory device according to claim 11, wherein the protruding portions are each a different width in a second direction crossing the first direction.

13. The memory device according to claim 11, wherein the contact pillars have a substantially rectangular shape when viewed from the first direction.

14. The memory device according to claim 13, wherein the contact pillars are wider than at least a portion of the respective protruding portion in a second direction crossing the first direction.

15. The memory device according to claim 11, further comprising:
a plurality of support pillars in the lead-out region, each support pillar extending in the first direction through the stacked body.

16. A method of manufacturing a semiconductor device, the method comprising:
forming a plurality of first trenches in a first material layer;
forming a stacked body by alternately stacking first insulating films and first sacrificial films in a first direction on the first material layer with the plurality of first trenches formed therein;
forming a plurality of holes that extend in the first direction through the stacked body, the holes each passing through a joining portion of a different first sacrificial film inside one of the plurality of first trenches;
removing a part of the first sacrificial films from an inner side face of the holes;
forming a second insulating film on the inner side face of the holes;
removing the second insulating film to expose the joining portions inside the plurality of first trenches;
embedding a second sacrificial film in the plurality of holes after the joining portions are exposed;
replacing the first sacrificial films with first conductive films; and
forming a plurality of first pillars by replacing the second sacrificial film with a conductor.

17. The method of manufacturing the semiconductor device of claim 16, wherein the first material film is an insulating material.

18. The method of manufacturing the semiconductor device of claim 16, wherein the plurality of first trenches each have a different width in a direction crossing the first direction so the different first sacrificial film closes the respective trench by forming the respective joining portion.

19. The method of manufacturing the semiconductor device of claim 16, wherein the holes extend beyond an outer edge of the joining portion when viewed from the first direction.

20. The method of manufacturing the semiconductor device of claim 16, further comprising:
after forming the stacked body, forming a plurality of second trenches in the stacked body; and
forming another stacked body on the previously formed stacked body and the plurality of second trenches by alternately stacking first insulating films and first sacrificial films in the first direction, wherein
the plurality of holes extend in the first direction through both stacked bodies.
